(19) United States
(12) Patent Application Publication
(10) Pub. No.: US 2022/0073343 A1
(43) Pub. Date: Mar. 10, 2022

(54) METHOD FOR TRANSFERRING A SURFACE LAYER TO CAVITIES

(71) Applicant: Soitec, Bernin (FR)

(72) Inventor: Bruno Ghyselen, Seyssinet (FR)

(21) Appl. No.: 17/416,368

(22) PCT Filed: Dec. 12, 2019
(86) PCT No.: PCT/FR2019/053038

§ 371 Date: Jun. 18, 2021

(30) Foreign Application Priority Data
Dec. 20, 2018 (FR) 1873597

(51) Int. Cl. B81C 1/00

(52) U.S. Cl. CPC B81C 1/00357; B81C 2201/0195

(57) ABSTRACT

A method for transferring a superficial layer to a carrier substrate having cavities comprises: —providing a donor substrate, —providing the carrier substrate having a first face and comprising cavities, each cavity opening at the first face and having a bottom and peripheral walls, —creating at least one temporary pillar in at least one of the cavities, the pillar having an upper surface that is coplanar with the first face of the carrier substrate, joining the donor substrate and the carrier substrate at the first face of the carrier substrate, —thinning the donor substrate to form the superficial layer, and removing the at least one temporary pillar.

### CROSS-REFERENCE TO RELATED APPLICATIONS

This application is a national phase entry under 35 U.S.C. § 371 of International Patent Application PCT/FR2019/053038, filed Dec. 12, 2019, designating the United States of America and published as International Patent Publication WO 2020/128244 A1 on Jun. 25, 2020, which claims the benefit under Article 8 of the Patent Cooperation Treaty to French Patent Application Serial No. 1873597, filed Dec. 20, 2018.

### TECHNICAL FIELD

The present disclosure relates to the field of microelectronics and microsystems. It relates to, in particular, a process for transferring a superficial layer to a substrate comprising an array of cavities.

### BACKGROUND

MEMS devices (MEMS being the acronym of MicroElectroMechanical Systems) are widely used to fabricate various sensors, for a multitude of applications: mention may be made of, for example, pressure sensors, microphones, radiofrequency switches, electro-acoustic and ultrasonic transducers (piezoelectric micromachined ultrasonic transducers (pMUT), for example), etc.

Many of these MEMS devices are based on a flexible membrane overhanging a cavity. In operation, the deflection of the membrane, which is related to a physical parameter (for example, the propagation of an acoustic wave for a pMUT), is converted into an electrical signal (or vice versa depending on whether the device is in receiver or emitter mode).

To improve the performance of these on-cavity MEMS devices, it may be useful to employ a membrane having a good crystal quality and a uniform and well controlled thickness. Silicon-on-insulator (SOI) substrates are particularly suitable for the fabrication of these devices in that they offer a surface layer of very high quality, for forming the membrane, and a buried oxide layer (and/or a carrier substrate), for accommodating the subjacent cavity.

The publication by Lu Yipeng and David A. Horsley, “Modeling, fabrication, and characterization of piezoelectric micromachined ultrasonic transducer arrays based on cavity SOI wafers.” (Journal of Microelectromechanical Systems 24.4 (2015) 1142-1149) presents an example of fabrication of a pMUT device from an SOI substrate comprising buried cavities and the advantages that this procures.

Depending on the type of device implemented, the geometry of the cavity (shape, lateral dimensions, depth), of the membrane (thickness) and their planar distribution (inter-cavity distance) will be different. In certain geometry and distribution configurations it may thus turn out to be complex to fabricate substrates comprising a superficial layer placed on a plurality of cavities, and, in particular, to define a transferring process compatible with the transfer of a superficial layer of small thickness to cavities of large size.

### BRIEF SUMMARY

The present disclosure aims to overcome all or some of the aforementioned drawbacks. It relates to, in particular, a process for transferring a superficial layer to a substrate comprising a plurality of cavities.

The present disclosure relates to a process for transferring a superficial layer to a carrier substrate containing cavities, the process comprising:
providing a donor substrate,
providing the carrier substrate, the latter having a first side and containing cavities, each cavity opening onto the first side and having a bottom and peripheral walls,
producing at least one temporary pillar in a least one of the cavities, the pillar having an upper surface that is coplanar with the first side of the carrier substrate,
joining the donor substrate and the carrier substrate via the first side of the carrier substrate,
thinning the donor substrate, so as to form the superficial layer, and
removing the at least one temporary pillar.

According to other advantageous and non-limiting characteristics of the present disclosure, taken alone or in any technically feasible combination:
providing the donor substrate comprises implanting light species in the donor substrate to form a buried fragile region that lies between a first portion of the donor substrate, which portion is intended to form the superficial layer, and a second portion of the donor substrate, which portion is intended to form the rest of the donor substrate;
thinning the donor substrate comprises separating, via the buried fragile region, the surface layer from the rest of the donor substrate;
the first portion of the donor substrate has a thickness between 0.2 micron and 2 microns;
the at least one pillar is separate from the peripheral walls of the cavity;
the upper surface of the pillar has a circular, square, rectangular or cruciform outline;
the at least one pillar joins at least one peripheral wall of the cavity;
the upper surface of the at least one pillar forms a grid joining the peripheral walls of the cavity;
a plurality of pillars form an array of parallel walls that join at their ends the peripheral walls of the cavity;
the joining comprises direct bonding, on the one hand, the donor substrate, and, on the other hand, the first side of the carrier substrate and the upper surface of the at least one pillar;
removing the pillar comprises locally etching the superficial layer to form a through-aperture in the superficial layer, and chemically etching the pillar via the aperture;
the pillar is chemically etched by wet or dry etching;
the aperture is formed plumb with the pillar;
the aperture has a cross-sectional area smaller than or equal to the area of the upper surface of the pillar;
the aperture has a cross-sectional area larger than the area of the upper surface of the pillar;
the aperture is formed in the superficial layer, outside of regions overhanging the at least one cavity;
removing the pillar comprises locally etching the second side of the carrier substrate up to the cavity, in order to form an aperture that communicates with the cavity, and chemically etching the pillar via the aperture;
the pillar comprises at least one material chosen from silicon oxide, silicon nitride, single-crystal silicon, polysilicon, amorphous silicon and porous silicon;
and
the donor substrate comprises at least one semiconductor or piezoelectric material.

### BRIEF DESCRIPTION OF THE DRAWINGS

Other features and advantages of the present disclosure will become apparent from the following detailed description of example embodiments of the present disclosure, which description is given with reference to the accompanying figures, in which:

FIG. 1 shows a structure comprising a superficial layer placed on buried cavities, obtained using a transferring process according to the present disclosure;

FIGS. 2A-2J show steps of a transferring process according to the present disclosure;

FIGS. 3A-3C show other steps of a transferring process according to the present disclosure;

FIGS. 4A-4C show variants of a step of removing temporary pillars, which step is comprised in a transferring process according to the present disclosure; and

FIGS. 5A-51 show an example of an embodiment of the transferring process according to the present disclosure.

### DETAILED DESCRIPTION

In the description, the same references in the figures might be used for elements of the same type. The figures are schematic representations that, for the sake of legibility, are not to scale. In particular, the thicknesses of the layers along the z-axis are not to scale with respect to their lateral dimensions along the x- and y-axes; and the relative thicknesses of the layers with respect to one another are not necessarily respected in the figures.

The present disclosure relates to a process for transferring a superficial layer 10 to a carrier substrate 20 containing cavities 23 (FIG. 1), the transferring process leading to the fabrication of a structure 100 comprising buried cavities 23.

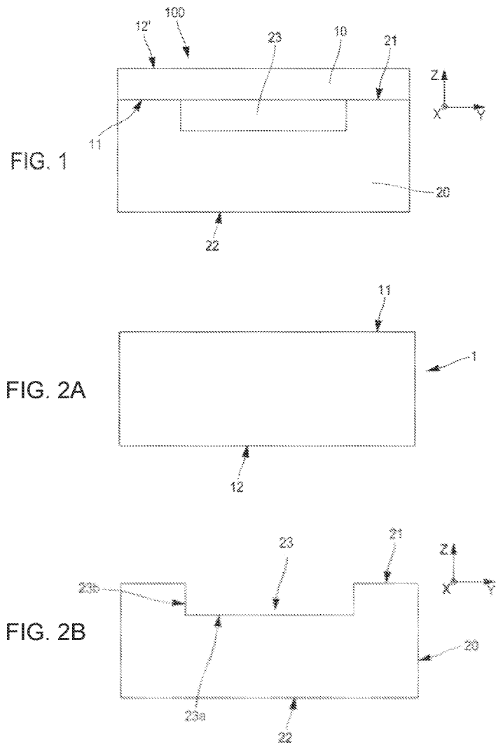

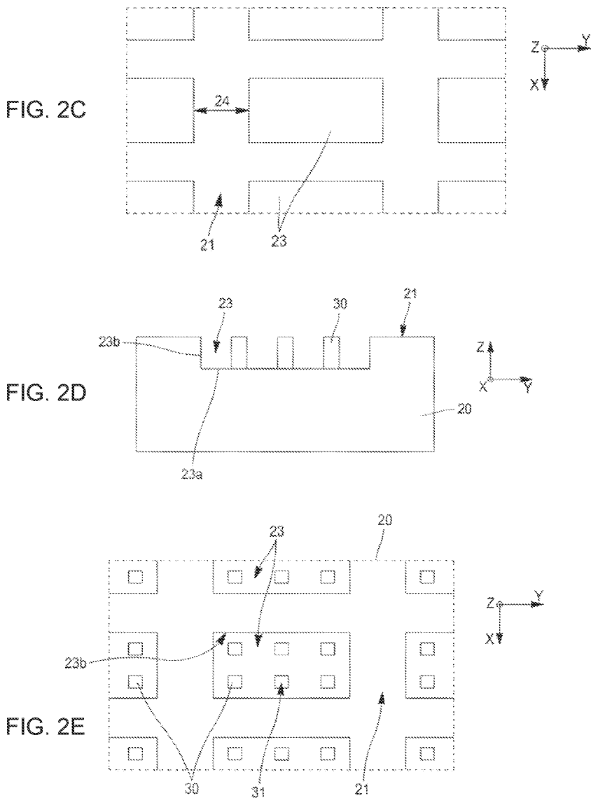

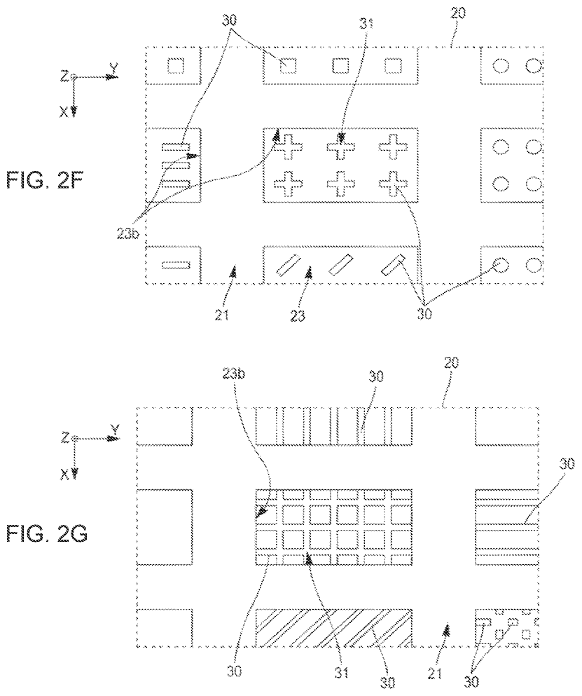

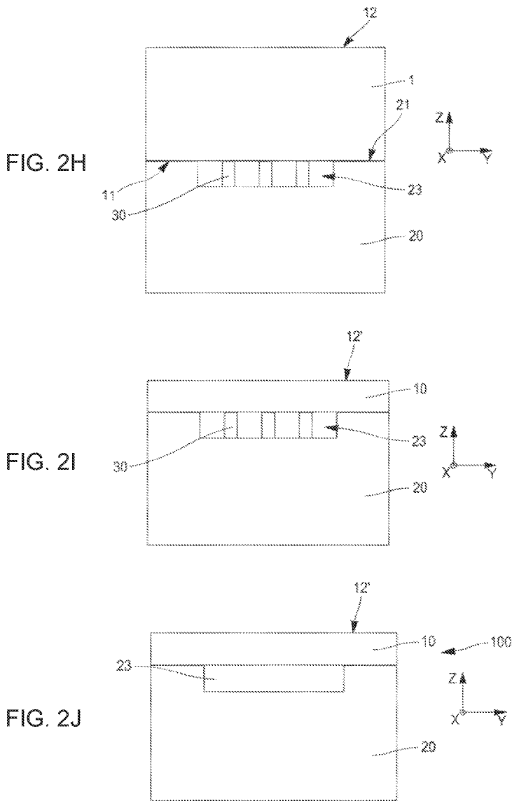

The process according to the present disclosure comprises a step of providing a donor substrate 1 having a front side 11, which is intended to be joined to the carrier substrate 20, and a back side 12 (FIG. 2A). By way of example, and non-limitingly, the donor substrate 1 will possibly comprise at least one semiconductor, for example, silicon, silicon carbide, gallium nitride, etc., or one piezoelectric material, for example, lithium tantalate, lithium niobate, aluminum nitride, zinc oxide, PZT, etc.

The process also comprises a step of providing the carrier substrate 20 (FIG. 2B); the latter has a first side 21, which is intended to be joined to the donor substrate 1, and a second side 22. By way of nonlimiting example, the carrier substrate 20 will possibly comprise silicon, glass, sapphire, etc. The carrier substrate 20 contains a plurality of cavities 23 that open onto its first side 21. Each cavity 23 has a bottom 23a and peripheral walls 23b.

The geometry of each cavity 23, which depends on the targeted MEMS device, is defined by:
the shape of the cavity 23 in the plane of the first side 21 of the carrier substrate 20 (called the main plane (x,y) in the rest of the description): it will possibly be circular, square, rectangular or polygonal;
the lateral dimensions of the cavity 23, in the main plane (x,y):
they will possibly vary from a few microns to a few millimeters; and
the depth of the cavity 23, along the z-axis normal to the main plane (x,y): it will possibly vary from a few tens of nanometers to a few tens of microns, or even a few hundred microns.

The planar distribution of the cavities 23, i.e., their distribution in the main plane (x,y) also depends on the targeted device and will define the inter-cavity spacing 24 (FIG. 2C): it will possibly vary from a few microns to a few hundred microns, or even a few millimeters. The inter-cavity spacing 24 will possibly be uniform and identical over the entire surface of the carrier substrate 20 or vary between regions on the surface of the carrier substrate 20.

It will be noted that the carrier substrate 20 will possibly contain cavities 23 having different shapes, lateral dimensions, depths and/or planar distributions, particularly if provision is made to co-integrate devices of various types into the structure 100 comprising buried cavities.

Various layers will possibly be deposited on the bottom 23a and/or on the peripheral walls 23b of the cavities 23 (for example, silicon nitride, silicon oxide, etc.) depending on the type of MEMS device intended to be produced with the structure 100 comprising buried cavities 23.

The transferring process according to the present disclosure furthermore makes provision for a step of producing at least one temporary pillar 30 in at least one of the cavities 23, and preferably in each cavity 23 (FIG. 2D). The number and position of the pillars 30 will possibly be chosen depending on the lateral dimensions of each cavity 23.

The pillar 30 has, in the main plane (x,y), an upper surface 31 that is coplanar with the first side 21 of the carrier substrate 20. The lower surface of the pillar 30 is securely fastened to the bottom 23a of the cavity 23.

By way of example, and non-limitingly, the pillar 30 comprises at least one material chosen from silicon oxide, silicon nitride, single-crystal silicon, polysilicon, amorphous silicon and porous silicon.

According to a first variant, the (or the more than one) pillar(s) 30 is (are) separate from the peripheral walls 23b of the cavity 23. As illustrated in FIG. 2E, the pillars 30 do not make contact with the peripheral walls 23b of the cavities 23. Preferably, they are uniformly distributed over the bottom 23a of each cavity 23.

The upper surface 31 of the pillar 30 will possibly have various types of outlines, a few examples of which are illustrated in FIG. 2F: a circular, square, rectangular or cruciform outline.

According to this first variant, the pillar 30 will possibly have dimensions ranging from a few microns to about 15 microns, for example, 5 microns, 7 microns or even 10 microns, for the diameter of a circular outline or the side length of a square or rectangular outline.

According to a second variant, the pillar 30 or some of a plurality of pillars 30 join at least one peripheral wall 23b of the cavity 23. A plurality of examples of pillars 30, each forming a partition, is illustrated in FIG. 2G. According to one example, the upper surface 31 of the pillar 30 (or of the pillars) forms a grid that joins the peripheral walls 23b of the cavity 23. According to another example, certain pillars 30 in a cavity join a peripheral wall 23b and others are separate. According to yet another example, the pillars 30 form an array of parallel partitions that join, at their ends, peripheral walls 23b of the cavity 23.

According to this second variant, the pillar 30 will possibly have a width ranging from a few microns to about 15 microns, for example, 5 microns, 7 microns or even 10 microns. It will possibly have a length ranging from a few microns up to a dimension allowing the peripheral walls 23b of the cavity 23 to be joined, and therefore of the order of magnitude of the dimensions of the cavity 23.

The transferring process according to the present disclosure also comprises a step of joining the donor substrate 1 and the carrier substrate 20 via the first side 21 of the carrier substrate 20 (FIG. 2H).

Advantageously, this step comprises direct bonding, by molecular adhesion, on the one hand, the front side 11 of the donor substrate 1, and, on the other hand, the first side 21 of the carrier substrate 20 and the upper surface 31 of the (at least one) pillar 30. The principle of molecular adhesion, which is well known in the prior art, will not be described in further detail here. It will be noted that the substrates must have a very good surface finish (cleanness, low roughness, etc.) for a joint of good quality to be obtained.

Particular care must be taken to obtain a good coplanarity between the first side 21 of the carrier substrate 20 and the upper surface 31 of each pillar 30 to ensure effective bonding of the first side 21 and the upper surface 31, with the front side 11 of the donor substrate 1.

Advantageously, in order to guarantee a joint of good quality, the joining step comprises cleaning the surfaces to be joined of the donor substrate 1 and of the carrier substrate 20, before the surfaces are brought into contact. By way of example, a conventional sequence used in microelectronics, especially for silicon-based substrates, comprises an ozone clean, an SC1 clean (SC1 being the acronym of Standard Clean 1) and an SC2 clean (SC2 being the acronym of Standard Clean 2) with intermediate rinses. The surfaces to be joined will also possibly be activated, for example, using a plasma, before being brought into contact, in order to promote a high bonding energy between the surfaces.

Optionally, the donor substrate 1 and/or the carrier substrate 20 will possibly comprise a bonding layer, on the front side 11 and/or on the first side 21, respectively, in order to promote bond quality and the bonding energy of their interface.

The transferring process then comprises a step of thinning the donor substrate 1 to form the superficial layer 10.

According to a first variant, the step of thinning the donor substrate 1 is carried out by mechanical grinding, by chemical-mechanical polishing and/or by chemical etching of the back side 12 thereof. At the end of the thinning step, a superficial layer 10 transferred to the carrier substrate 20 is obtained (FIG. 2I).

According to a second advantageous variant, the thinning is carried out using the SMART CUT™ process, which is based on an implantation of light ions and a detachment via the implanted region.

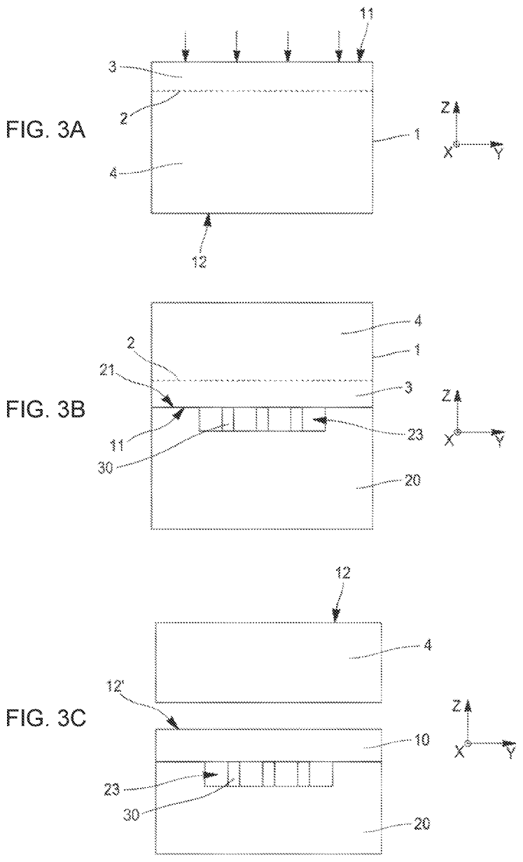

Thus, according to this second variant, the aforementioned step of providing the donor substrate 1 comprises implanting light species in the donor substrate 1, so as to form a buried fragile region 2 that lies between a first portion 3 of the donor substrate 1, which portion is intended to form the superficial layer 10, and a second portion 4 of the donor substrate, which portion is intended to form the rest of the donor substrate 1 (FIG. 3A).

The thickness of the first portion 3, and, therefore, of the future superficial layer 10, is dependent on the implantation energy of the light species (hydrogen or helium, for example). Advantageously, the implantation energy is chosen so that the first portion 3 of the donor substrate 1 has a thickness of about 0.2 micron-2 microns.

The donor substrate 1 is then joined to the carrier substrate 20 in the joining step of the process (FIG. 3B).

Still according to this second advantageous variant, the step of thinning the donor substrate 1 comprises separating, via the buried fragile region 2, the superficial layer 10 (formed by the detached first portion 3) and the second portion 4 of the donor substrate 1 (FIG. 3C). This separation preferably occurs during a heat treatment at a temperature between a few hundred degrees and 700° C. Alternatively, it may be mechanically assisted or achieved, after the heat treatment, by means of a mechanical stress.

At the end of the thinning step, a superficial layer 10 transferred to the carrier substrate 20 is obtained (FIG. 3C). It will be recalled that the SMART CUT™ process allows thin layers having an excellent thickness uniformity to be obtained. This criterion may be very advantageous for certain MEMS devices requiring flexible membranes of controlled thickness.

In certain cases where the thickness of the superficial layer 10 transferred using the SMART CUT™ process is insufficient, it is possible to increase this thickness again by depositing an additional layer on the free surface 12′ of the superficial layer 10, for example, by epitaxial growth or other known deposition methods, during the finishing processing that is mentioned below.

In both the described variants, after the superficial layer 10 has been transferred to the carrier substrate 20, the thinning step may comprise finishing processing aiming to improve the crystal quality (removal of defects from the layer), the surface quality (removal of residual roughness from the free surface 12′) and/or to modify the thickness of the superficial layer 10. This processing will possibly include one or more heat treatments, chemical-mechanical polishes, chemical etches, epitaxial growth and/or deposition of additional layers.

The role of the (at least one) temporary pillar 30 located in the cavity 23 is to mechanically support the superficial layer 10 during the thinning step.

The superficial layer 10 overhanging the cavity 23 is liable to deform during chemical-mechanical thinning according to the aforementioned first variant.

Furthermore, according to the described second variant, the superficial layer 10 risks not being transferred facing the cavity 23 if the stiffening effect against the front side 11 of the donor substrate 1 is insufficient during the weakening of the buried fragile region 2 and up to the separation of the first and second portions 3, 4 of the donor substrate 1. The (at least one) temporary pillar 30 located in the cavity 23 ensures this stiffening effect against the front side 11 and thus allows complete transfer of the superficial layer 10 to the entirety of the carrier substrate 20, and especially above the cavities 23.

Advantageously, for a superficial layer 10 of a thickness of about 1 micron to 1.5 microns, the spacing between the pillars 30 themselves and the spacing between the peripheral walls 23b of the cavity 23 and each pillar 30 is chosen to be between 10 microns and 50 microns, and preferably is about 20 microns.

The transferring process according to the present disclosure lastly comprises a step of removing the (at least one) temporary pillar 30.

Removing the pillar 30 may comprise locally etching the superficial layer 10 in order to form at least one through-aperture 13a, 13b, 13c in the superficial layer 10.

Such local etching may be carried out by photolithography and dry or wet chemical etching. In particular, a mask deposited on the free surface 12′ of the superficial layer 10 allows the regions to be etched to form the apertures to be defined and the rest of the free surface 12′ to be protected. It will be noted that alignment marks, defined on the periphery of the carrier substrate 20 and/or in regions provided for dicing lanes on the first side 21 thereof and/or on the second side 22 of the carrier substrate 20, during the formation of the cavities 23 and of the pillars 30 on the carrier substrate 20, allow a precise positioning to be achieved with respect to the buried cavities 23 and pillars 30 during the step of removing the one or more pillars. These marks will possibly also serve in subsequent steps requiring alignment with respect to the cavities 23 in the structure 100 comprising buried cavities.

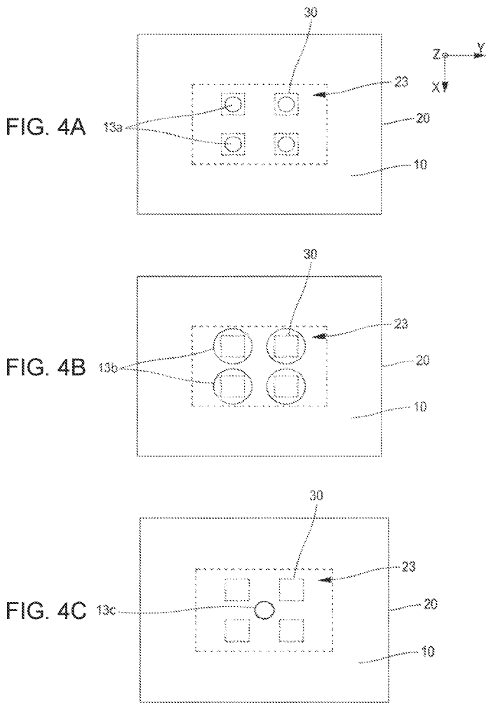

FIGS. 4A-4C show enlargements, seen from above, of the superficial layer 10, the outline of the subjacent cavity 23 and the upper surfaces 31 of the pillars 30 having been drawn with dashed lines. The aperture 13a, 13b, 13c may especially be produced with any one of the configurations shown in these figures.

As illustrated in FIG. 4A, the aperture 13a may be produced plumb with each pillar 30, and have a cross-sectional area smaller than the area of the upper surface 31 of the pillar 30. Dry or wet chemical etching suitable for etching the material of the pillar 30 is then carried out, via the aperture 13a, in order to remove the pillar 30 and release the superficial layer 10 over the entire extent of the cavity 23.

Alternatively, the aperture 13b may be produced plumb with each pillar 30, and have a cross-sectional area larger than the area of the upper surface 31 of the pillar 30 (FIG. 4B). Dry or wet chemical etching is carried out, via the aperture 13a, in order to remove the pillar 30 and release the superficial layer 10 over the entire extent of the cavity 23.

Again alternatively, the aperture 13c (or a plurality of apertures) may be produced in a region of the superficial layer 10 overhanging the cavity 23 (FIG. 4C). Wet chemical etching is carried out, via the aperture 13a, in order to remove the pillar 30 and release the superficial layer 10 over the entire extent of the cavity 23.

It will be noted that, for each of the configurations presented in FIGS. 4A-4C, it is possible to plug the apertures 13a, 13b, 13c, for example, by depositing polysilicon, under vacuum or a controlled atmosphere.

According to one variant (not shown), removing the pillar 30 may comprise locally etching the superficial layer 10 in order to form at least one through-aperture 13 in the superficial layer 10 in a region not located plumb with a cavity 23. In this case, the aperture 13 opens into a lateral channel, produced in the carrier substrate 20 prior to the joining step of the process; this lateral channel communicates with one or more surrounding cavities 23. Dry or wet chemical etching may then be carried out, via the aperture 13 and the lateral channel, in order to remove the (at least one) pillar 30 and release the superficial layer 10 over the entire extent of the cavity 23.

It will be noted that this variant allows the membrane (portion of the superficial layer 10 located plumb with a cavity 23) to be left integral by avoiding passage of the aperture 13 therethrough.

According to another variant (not shown), removing the pillar 30 may comprise forming at least one aperture 13 by locally etching the second side 22 of the carrier substrate 20, up to the cavity 23. Advantageously, such etching of the second side 22 is carried out at the end of the fabrication of the MEMS device, when the carrier substrate 20 is thinned, for example, to 400, 200, 100, 50 microns or less. This allows an aperture 13 of small size to be produced while remaining within ratios of etched thickness/dimensions of the aperture that are accessible using known chemical etching techniques.

At the end of the step of removing the one or more temporary pillars 30, a structure 100 comprising buried cavities, which are suitable for fabricating MEMS devices because the geometry of the cavities 23, the thickness of the superficial layer 10 (flexible membrane) and the planar distribution of the cavities/membranes meet the specifications of MEMS devices. The transferring process according to the present disclosure allows a high-quality superficial layer 10, and, in particular, a superficial layer 10 having a small thickness (smaller than a few microns), to be transferred to cavities of any geometry, and, in particular, cavities having large dimensions (larger than a few tens of microns), by virtue of the use of temporary pillars 30, present in the cavities 23, during the thinning step that forms the superficial layer 10.

### Example of an Embodiment

In the present example, it is sought to form a structure 100 comprising buried cavities 23 comprising a superficial layer made of silicon of 1.5 microns thickness and cavities of 250 microns side length, 0.5 micron depth and spaced apart by 100 microns.

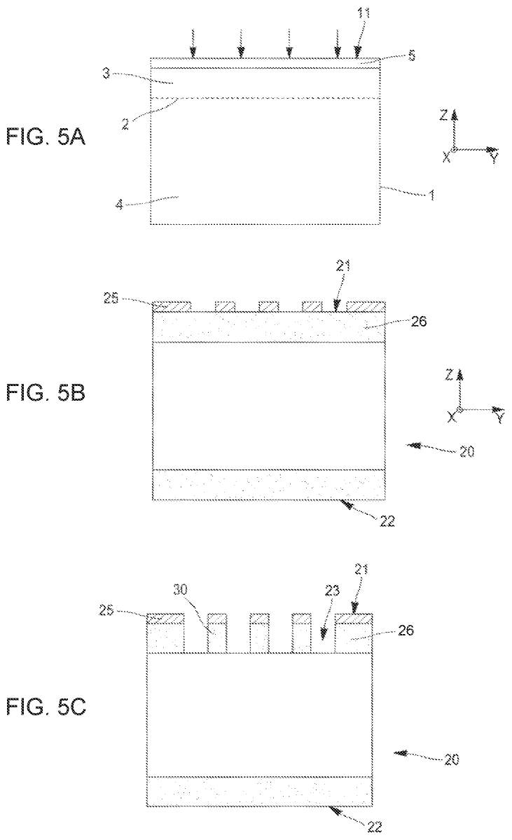

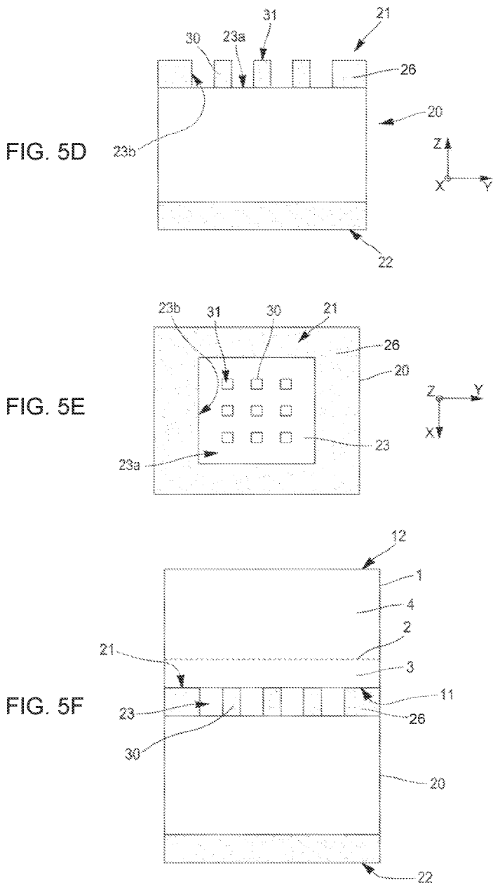

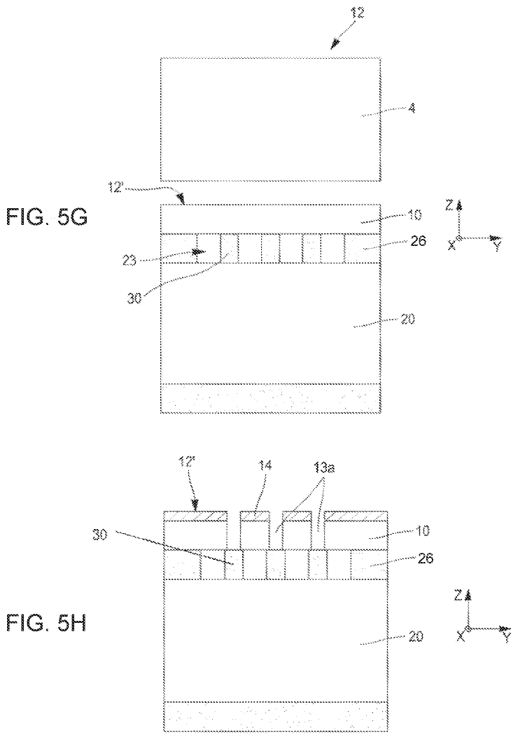

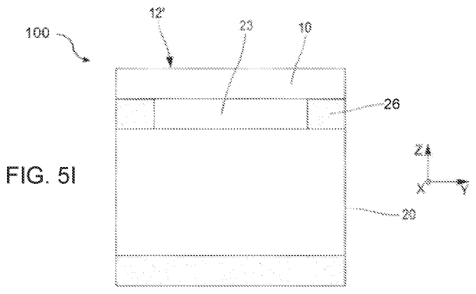

The donor substrate 1 is a substrate made of silicon (FIG. 5A). An oxide layer 5, for example, of about 50 nm thickness, is formed, for example, by thermal oxidation, on the front side 11 thereof prior to the implantation of the light species. The implantation energy is set to 210 keV, with hydrogen species at a dose of about 7^{E}16/cm². Thus, a buried fragile region 2, lying between a first portion 3 and a second portion 4 of the donor substrate 1, is formed.

The oxide layer 5 will possibly be preserved or removed prior to the step of joining to the carrier substrate 20.

The carrier substrate 20 is a substrate made of silicon. A thermal-oxide layer 26 having a thickness of 0.5 micron is formed on the carrier substrate 20 on its first side 21 and on its second side 22. The thermal-oxide layer present on the second side 22 will possibly be partially or entirely preserved, or removed depending on the circumstances. Alternatively, an oxide layer will possibly be deposited (using a known deposition technique) solely on the first side 21 of the carrier substrate 20.

By photolithography, a mask 25 is then defined on the first side 21 of the carrier substrate 20, comprising unmasked regions in which the thermal-oxide layer 26 will be able to be etched and masked regions in which the layer 26 will be protected (FIG. 5B). It will be noted that alignment marks are also defined on the periphery of the carrier substrate 20 and/or in the regions of the dicing lanes, for subsequent photolithography steps that will need to be able to determine the coordinates of the cavities 23, when they are buried under the superficial layer 10.

The unmasked regions are defined depending, on the one hand, on the size and intended planar distribution of the cavities 23 of the structure 100 and, on the other hand, on the arrangement of the temporary pillars 30.

Typically, in the present case, each cavity 23 measures 250 microns per side, and temporary pillars 30 are placed at 25 microns from the peripheral walls 23b of the cavity 23 and spaced apart from one another by 25 microns. The upper surface 31 of each pillar 30 is square with a side length of 7 microns; alternatively, the upper surface 31 will possibly be circular with a diameter of 7 microns or cruciform with the largest of the dimensions of the cross set to 7 microns.

In the unmasked regions, dry or wet chemical etching of the thermal-oxide layer 26 is carried out right through its thickness, i.e., 0.5 micron (FIG. 5C). The mask 25 is then removed.

Thus, a carrier substrate 20 comprising a plurality of cavities that open onto its first side 21 and in which are placed temporary pillars 30 the upper surface 31 of which is coplanar with the first side 21 of the carrier substrate 20 is obtained (FIGS. 5D and 5E).

After a cleaning and activating sequence, the front side 11 of the donor substrate 1 and the first side 21 of the carrier substrate 20 are brought into contact and direct bonded (FIG. 5F). It will be noted that the direct bonding will possibly be carried out under ambient atmosphere or under a controlled atmosphere (pressure and nature of the gas) or under vacuum. An anneal for consolidating the bonding interface may be applied to the bonded structure at a temperature of about 350° C.

The separation via the buried fragile region 2 is carried out during a detaching heat treatment, at a temperature of about 500° C.

A superficial layer 10 transferred to the carrier substrate 20 is then obtained (FIG. 5G).

Finishing processing operations, such as a thermal oxidizing process and a chemical-mechanical polish are preferably carried out in order to guarantee that the transferred superficial layer 10 has a good surface and structural quality and to obtain a thickness of 1.5 micron.

For the step of removing the temporary pillars 30, a mask 14, for example, made of silicon nitride, is defined by photolithography, using alignment marks provided on the carrier substrate 20, in order to define unmasked regions in which the through-apertures 13a in the superficial layer will be formed, the rest of the free surface 12′ of the superficial layer 10 being masked and therefore protected. Dry or wet local etching of the superficial layer 10 made of silicon is carried out in order to form the apertures 13a, the cross-sectional area of each 13a here being chosen to be smaller than the area of the upper surface 31 of each pillar 30 (FIG. 5H).

In the presence of the apertures 13a, a chemical etch, for example, a dry chemical etch, based on hydrofluoric acid (HF) vapor, is carried out to remove the thermal oxide from which the pillars 30 are made, and thus release the superficial layer 10 over the entire extent of the cavity 23.

The mask 14 may be removed, before the chemical etch of the pillars 30 or at the end of the step of removing the pillars 30.

The apertures 13a may then be plugged if necessary.

A structure 100 comprising buried cavities 23 (FIG. 5I) and suitable for fabricating MEMS devices because the geometry of the cavities 23, the thickness of the superficial layer 10 (flexible membrane) and the planar distribution of the cavities/membranes meet the aforementioned specifications, is obtained. The transferring process according to the present disclosure allows a high-quality superficial layer 10, and, in particular, a superficial layer 10 having a small thickness (about 1 micron in this example), to be transferred to cavities of any geometry, and in particular, cavities having large dimensions (250×250 microns in this example), by virtue of the use of temporary pillars 30, placed in the cavities 23, during the thinning step that forms the superficial layer 10.

Of course, the present disclosure is not limited to the described embodiments and examples, and variant embodiments may be introduced thereinto without departing from the scope of the invention as defined by the claims.

1. A method of transferring a superficial layer to a carrier substrate containing cavities, the method comprising:
providing a donor substrate,
providing the carrier substrate, the carrier substrate having a first side and containing cavities, each cavity opening onto the first side and having a bottom and peripheral walls;
producing at least one temporary pillar in a least one of the cavities, the at least one temporary pillar having an upper surface that is coplanar with the first side of the carrier substrate,
joining the donor substrate and the carrier substrate via the first side of the carrier substrate;
thinning the donor substrate to form the superficial layer, and
removing the at least one temporary pillar.

2. The method of claim 1, wherein:
providing the donor substrate comprises implanting light species in the donor substrate to form a buried fragile region that lies between a first portion of the donor substrate, which portion is intended to form the superficial layer, and a second portion of the donor substrate, which portion is intended to form a remainder of the donor substrate, and
thinning the donor substrate comprises separating, via the buried fragile region, the superficial layer from the remainder of the donor substrate.

3. The method of claim 2, wherein the first portion of the donor substrate has a thickness between 0.2 micron and 2 microns.

4. The method of claim 1, wherein the thinning of the donor substrate comprises at least one mechanical grinding operation and/or at least one chemical-mechanical polishing operation and/or at least one chemical etching operation carried out on a back side thereof.

5. The method of claim 1, wherein the at least one temporary pillar is separate from the peripheral walls of the cavity.

6. The method of claim 5, wherein the upper surface of the at least one temporary pillar has a circular, square, rectangular or cruciform outline.

7. The method of claim 1, wherein the at least one temporary pillar joins at least one peripheral wall of the cavity.

8. The method of claim 7, wherein the upper surface of the at least one temporary pillar forms a grid that joins the peripheral walls of the cavity.

9. The method of claim 7, wherein the at least one temporary pillar comprises a plurality of temporary pillars forming an array of parallel walls that join at their ends the peripheral walls of the cavity.

10. The method of claim 1, wherein the joining comprises direct bonding, on the one hand, the donor substrate, and, on the other hand, the first side of the carrier substrate and the upper surface of the at least one temporary pillar.

11. The method of claim 1, wherein removing the at least one temporary pillar comprises locally etching the superficial layer to form a through-aperture in the superficial layer, and chemically etching the at least one temporary pillar via the through-aperture.

12. The method of claim 11, wherein the through-aperture is formed plumb with the at least one temporary pillar.

13. The method of claim 11, wherein the through-aperture has a cross-sectional area smaller than the area of the upper surface of the at least one temporary pillar.

14. The method of claim 11, wherein the through-aperture has a cross-sectional area larger than the area of the upper surface of the at least one temporary pillar.

15. The method of claim 11, wherein the through-aperture is formed in the superficial layer, outside of regions overhanging the at least one cavity.

16. The method of claim 1, wherein removing the at least one temporary pillar comprises locally etching a second side of the carrier substrate up to the cavity to form an aperture that communicates with the cavity, and chemically etching the at least one temporary pillar via the aperture.

17. The method of claim 1, wherein the at least one temporary pillar comprises at least one material chosen from among silicon oxide, silicon nitride, single-crystal silicon, polysilicon, amorphous silicon and porous silicon.

18. The method of claim 1, wherein the donor substrate comprises at least one semiconductor or piezoelectric material.
